(19) United States
(12) Patent Application Publication
(10) Pub. No.: US 2019/0363060 A1
(43) Pub. Date: Nov. 28, 2019

(54) APPARATUSES AND METHODS FOR PIN CAPACITANCE REDUCTION INCLUDING BOND PADS AND CIRCUITS IN A SEMICONDUCTOR DEVICE

(71) Applicant: MICRON TECHNOLOGY, INC., BOISE, ID (US)

(72) Inventors: Michael V. Ho, Allen, TX (US); Guy S. Perry, Plano, TX (US)

(73) Assignee: MICRON TECHNOLOGY, INC., BOISE, ID (US)

(21) Appl. No.: 15/990,370

(22) Filed: May 25, 2018

(51) Int. Cl. H01L 23/00; H01L 27/02; H01L 23/528

(52) U.S. Cl. CPC H01L 24/05; H01L 27/0296; H01L 28/20; H01L 2224/0557; H01L 23/528

(57) ABSTRACT

Apparatuses and methods for including bond pads and circuits in a semiconductor device are disclosed. An example apparatus includes a bond pad including one or more metal layers and one or more circuits. The circuits include one or more layers overlapped with the bond pad and coupled to metal layers of the bond pad. The pin capacitance can be reduced by overlapping of related layers and minimizing the areas of the unrelated layers.

### BACKGROUND

New generation memory technologies require the bond pad size to be smaller and pin capacitance to be reduced. Pin capacitance may be a resultant capacitive coupling between components in a circuit and bond pads, to which the connector pins are connected. Pin capacitance may be caused by the capacitive loadings of circuitries coupled to the bond pads. For example the reduced size of the bond pad from future process generations may reduce the layout space and cause the circuitry to be further away from the bond pad, which causes fringing capacitance and/or resistance-capacitance (RC) parasitics due to long routings. Pin capacitance may also be caused by the capacitance between different layers in a circuit when the different layers have different voltages. This may occur in any circuit that are coupled to the bond pads, such as an input driver, an output driver, an electrostatic-discharge (ESD) protection circuits, and/or parasitic routings.

New generation memory technologies also require smaller die size, higher speed and lower power consumption in a memory. For example, double data rate fifth-generation (DDR5) memory operates at higher speed and lower power running at lower voltage as compared to DDR4 memory. For example, the output stage drain power voltage (VDDQ) has reduced from 1.2 volts in DDR4 memory to 1.1 volts in DDR5 memory; speed binning in DDR5 memory has also doubled than that in DDR4 memory. This causes the sizes of the drivers to increase significantly in order to be able to detect small signals. For example, the output drivers with metal oxide semiconductor (MOS) devices and metal layer are becoming larger, making it difficult to design the layout of the circuits in a memory device. Similarly, input buffers in DDR5 memory are larger and more complex than those in DDR4 memory. Further, the maximum pin capacitance allowed in DDR5 memory is reduced to 0.9 pf from 1.4 pf in DDR4 memory. These considerations in the design need an improved layout of the memory circuits and bond pads.

### BRIEF DESCRIPTION OF THE DRAWINGS

The present solution will be described with reference to the following figures, in which like numerals represent like items throughout the figures.

FIG. 1 is a block diagram of an example semiconductor device including bond pads and circuits in accordance with examples described herein.

FIG. 2 illustrates examples of circuitry that may be coupled to bond pads in a semiconductor device in accordance with examples described herein.

FIGS. 3A-3B illustrate examples of various layouts of circuits relative to the bond pad in accordance with examples described herein.

FIG. 4 is a cross-section diagram illustrating the layout of some components in a circuit relative to the bond pad in accordance with examples described herein.

FIG. 5 is a top plan view of some components in a circuit relative to the bond pad in accordance with examples described herein.

FIG. 6A illustrates an example of an input driver.

FIG. 6B is a cross-section diagram illustrating the layout of some components of an input driver relative to the bond pad in accordance with examples described herein.

### DETAILED DESCRIPTION

Certain details are set forth below to provide a sufficient understanding of embodiments of the disclosure. However, it will be clear to one having skill in the art that embodiments of the disclosure may be practiced without these particular details. Moreover, the particular embodiments of the present disclosure described herein are provided by way of example and should not be used to limit the scope of the disclosure to these particular embodiments.

The “overlap” of two components in a semiconductor device may include a geometrical relationship between the two components, in which, when viewed from the top or bottom, one component covers at least a portion of the other component. For example, a bond pad may be stacked upon a circuit component including at least a portion that is positioned under the bond pad. When viewed from the top, the bond pad covers the circuit component or portion of the circuit component, thus the bond pad is overlapped with the circuit component.

The “overlapped area” of two overlapping components may refer to the area that, as viewed from above, is under a first component. The overlapped area is defined by the size of the first component. Overlapping components are positioned or extend at least partially in the overlapped area. For example, a second component that is covered by the first component is positioned in the overlapped area that is under the first component. In another example, with reference to a bond pad, the overlapped area refers to the area under the bond pad and defined by the size of the bond pad. If a bond pad is stacked upon at least a portion of a circuit, the portion of the circuit that is under the bond pad is in the overlapped area.

“Overlap” includes the geometrical relationships of components that are “entirely overlapped” and “partially overlapped.” A first component being “entirely overlapped” with a second component in a semiconductor device may refer to a situation in which the first and second components are overlapped and the entire portion of the first component is in the overlapped area. A first component being “partially overlapped” with a second component in a semiconductor device may refer to a situation in which the first component and second components are overlapped and less than the entire portion of the first component is in the overlapped area. In other words, at least a portion of the first component is not in the overlapped area. For example, a component may be partially overlapped with a bond pad when, viewed from the top, the bond pad covers at least a portion of the component so that at least another portion of the component is not in the overlapped area. The terms “overlap,” “overlapped area,” “entirely overlapped,” and “partially overlapped” are further described with reference to various examples disclosed herein in this document.

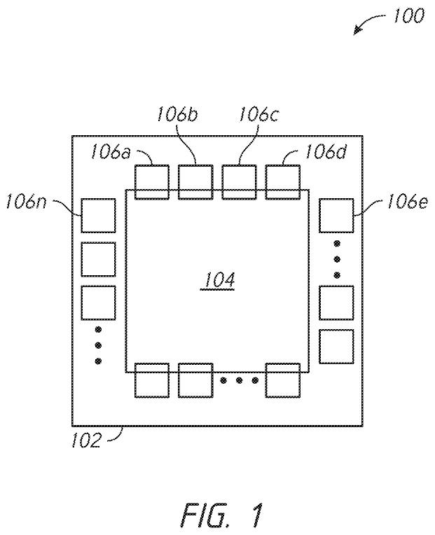

In FIG. 1, a semiconductor device 100 may include a die 102, one or more circuits 104, and multiple bond pads 106a-106n coupled to the one or more circuits 104. In some scenarios, at least one of the multiple bond pads 106a-106n is overlapping with a circuit that is coupled to the bond pad. A bond pad may be an input/output (I/O) bond pad that is connected to an in pin, an out pin, or an in/out pin that facilitates writing data, reading data, or write/read data to/from the circuit to which the bond pad is coupled. A bond pad may also be a power bond pad that is connected to a power that facilitates power to a circuit, e.g., an input driver of a memory device. In some scenarios, each of the multiple bond pads 106a-106n may have one or more metal layers. For example, a bond pad may include metal 0 (M0), metal 1 (M1), metal 2 (M2), or metal 3 (M3) layers from bottom to top, above which metal 3 layer may be connected to a pin. In some non-limiting examples, M0 include tungsten, M1 and M2 layers may include copper, and M3 may include aluminum. The bond pad may also include insulation layers disposed between the multiple metal layers. Similarly, a circuit 104 may have similar metal layers, e.g., M0, M1, M2, or M3 from bottom to top. In some examples, the bond pads 106a-106n and one or more circuits 104 may each have any suitable number of layers. For example, an additional metal layer, e.g., M4 may be provided. Any of the metal layers of the circuit may be coupled to a metal layer of the bond pad. For example, a metal layer of an I/O bond pad (such as one of 106a-106n) may be coupled to a metal layer of an I/O circuit (such as a circuit in circuits 104) so that the one or more circuits 104 may provide read data or receive write data through the I/O bond pad. As shown in FIG. 1, in some examples, one or more bond pads, e.g., 106a-106d are overlapped with one or more circuits in circuits 104. In other examples, one or more bond pads, e.g., 106e, 106n are not overlapped with any circuit in circuit 104. When one or more circuits in circuits 104 are overlapped with one or more bond pads, various components in circuits 104 may be positioned relative to the bond pads to reduce pin capacitance. The layout of the bond pads and the circuits, and the advantages are described further as below.

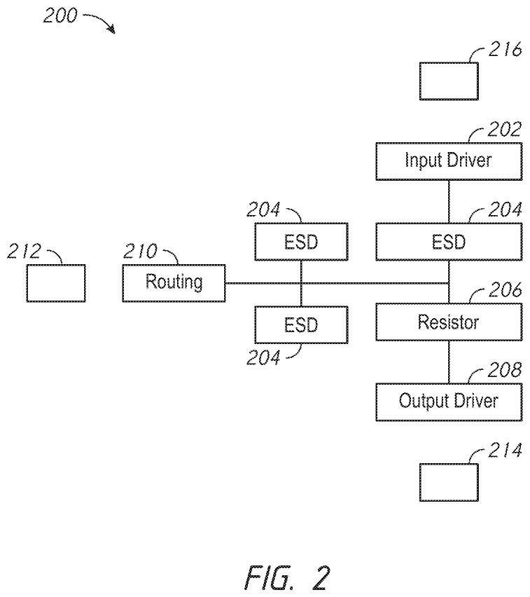

In FIG. 2, examples of circuits that may be coupled to a bond pad in a memory device are described. These circuits may contribute to undesirable capacitance, e.g., pin capacitance. Circuits that may be coupled to a bond pad in a memory device may include an input driver 202, an output driver 208, or a resistor 206. The circuit may have also have multiple ESD protection circuits 204 coupled to the bond pads. In some examples, an ESD protection circuit 204 may be coupled to another circuit and a bond pad to protect that another circuit coupled to the bond pad from being damaged by a high voltage charge. For example, an ESD protection circuit 204 may be coupled to a bond pad 214 and output buffer 208 of the memory. An ESD circuit may also be coupled to a power bond pad 216 and input buffer 202 of the memory. In some scenarios, the circuit may also include a conductive routing 210 that is coupled to a bond pad 212. Depending on the layout of the circuit and the bond pad, if the routing is long, it may generate undesirable RC parasitics. For example, for I/O circuitries carrying high current to communicate with external devices (e.g., outside the memory device), the drivers may be large in size that require long and wide routings, causing RC parasitics. Other undesirable capacitance may include: overlapping capacitance between unrelated layers having different voltages in the circuit; planar line to line (side to side) capacitance: or fringing capacitance by electrical field associated with flow of charge in a conductor. Various layouts described in this document may provide the reduction of pin capacitance.

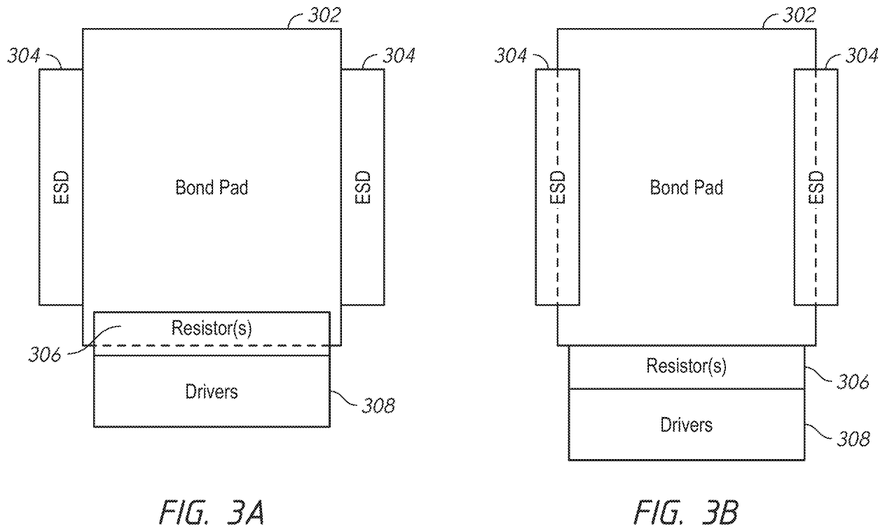

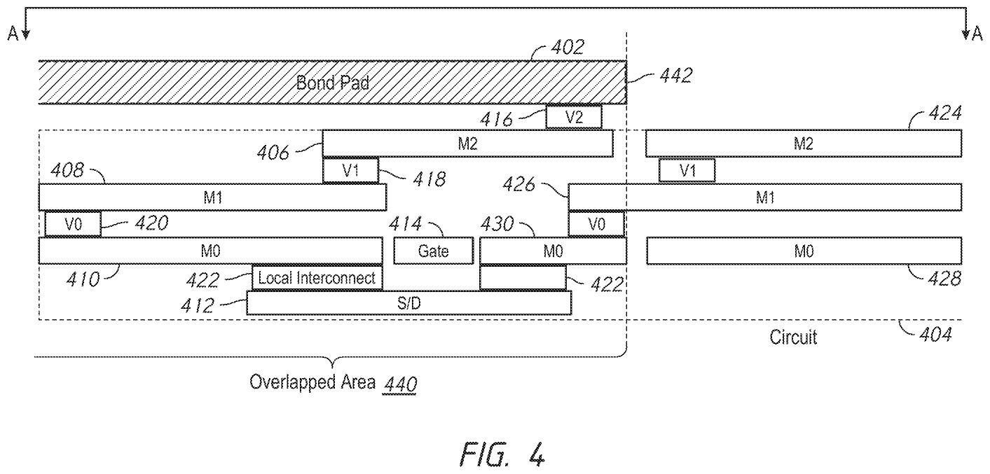

FIGS. 3A-3B illustrate examples of various layouts of circuits relative to the bond pad in accordance with examples described herein. In FIG. 3A, in some examples, a resistor 306 of a circuit may be positioned to overlap with the bond pad 302. This makes room for other components in the circuit. For example, the drivers 308 may be arranged to be closer to the bond pad. Alternatively, and/or additionally, in FIG. 3B, one or more ESD protection circuits 304 may be positioned to overlap with the bond pad 302. It is appreciated that variations of FIGS. 3A-3B may be possible. For example, one of the ESD protection circuits 304 may be positioned to overlap with the bond pad 302. In some examples, a resistor 306 may overlap with the bond pad 302 whereas one or more ESD protection circuits 304 also overlap with the bond pad 302. Alternatively, and/or additionally, other components in FIG. 2 may be positioned to overlap with the bond pad. Further details are described with reference to FIG. 4.

FIG. 4 is a cross-section diagram illustrating the layout of some components in a circuit relative to the bond pad in accordance with examples described herein. A bond pad 402 may be coupled to a circuit 404. Circuit 404 may have several components. For example, circuit 404 may have an output driver, which has a source/drain (S/D) layer 412. Circuit 404 may include a metal layer (e.g., M0 layer 410) disposed on S/D layer 412. Circuit 404 may also include one or more additional metal layers, e.g., M1 (408), M2 (406). Similar to the metal layers in the bond pad, M0 (410) may include tungsten, and M (408) or M2 (406) may include copper. Other suitable materials may also be possible.

In some scenarios, a first layer in the circuit, such as metal layer M2 (406) may be coupled to a metal layer (not shown) in the bond pad so that the circuit 404 is coupled to the bond pad 402. For example, metal layer M2 (406) may be coupled to bond pad 402 by a conductive via 416. As shown in FIG. 4, metal layer M2 is overlapped with bond pad 402 and at least a portion of metal layer M2, e.g., 406 is positioned to be inside the overlapped area 440. Here, metal layer M2 is overlapped with bond pad 402 because in a top view A-A, bond pad 402 covers at least a portion of metal layer M2, such as portion 406. As shown in FIG. 4, the overlapped areas 440 refers to the area under the bond pad 402 and that is defined by the size of the bond pad 402. For example, the overlapped area 440 is defined at least by an edge 442 of the bond pad 402, and thus a portion of metal layer M2, e.g., portion 406 is positioned inside the overlapped area 440.

With further reference to FIG. 4, an additional layer, e.g., a second layer, e.g., metal layer M1, in the circuit 404 may be overlapped with the bond pad 402 where at least a portion of the second layer, e.g., portion 408 is positioned inside the overlapped area 440. In some examples, other additional metal layers, e.g., metal layer M0 may also be overlapped with bond pad 402. For example, at least a portion of metal layer M0, e.g., portion 410, is covered by the bond pad 402 when viewed from the top (shown in A-A). In a non-limiting example, another layer, e.g., source/drain (S/D) of a transistor 412 may also be overlapped with bond pad 402. In some scenarios, various portions of the multiple layers illustrated herein in the circuit 404 may be parts of one or more circuits, such as those shown in FIG. 2. For example, S/D layer 412 may be a component of an output driver that may be coupled to the bond pad 402. In some scenarios, multiple layers of the circuit 404 may be connected by conductive vias, e.g., 420, 416, or by local interconnects (contacts), e.g., 422.

In some scenarios, a third layer in the circuit 404 may also be overlapped with the bond pad so that the second layer is disposed between the bond pad and the third layer. For example, S/D layer 412 of the output driver may be overlapped with the bond pad 402 such that at least a portion of the second layer, e.g., metal layer M1 is disposed between the S/D layer 412 and the bond pad 402. Additionally, the third layer may be coupled to the second layer. For example, the S/D layer 412 may be coupled to the metal layer M1 layer via local interconnect 422, metal layer M0 (portion 410) and conductive via 420.

It is appreciated that variations of the layouts described herein may be possible. For example, other additional components in the circuit 404, such as the gate of the output driver 414, or other portions of M0. M1 or M2 metal layers, e.g., portions 426, 430 may be overlapped with the bond pad 402. Alternatively, and/or additionally, any of the components in the circuit 404 may be entirely, or partially overlapped with the bond pad 402. In a non-limiting example, portion 408 of metal layer M 1, portion 410 of metal layer M0, or S/D layer 412 may be entirely overlapped with (under) the bond pad 402. In a non-limiting example, other portions of a particular layer, e.g., portion 424 of metal layer M2, portion 426 of metal layer M1, portion 428 of metal layer M0 may be partially overlapped or not overlapped with the bond pad 402. As various portions in circuit 404 may include components of one or more circuits that may be coupled to the bond pad, the layout of these portions relative to the bond pad may provide advantages in reducing the pin capacitances caused by these one or more circuits.

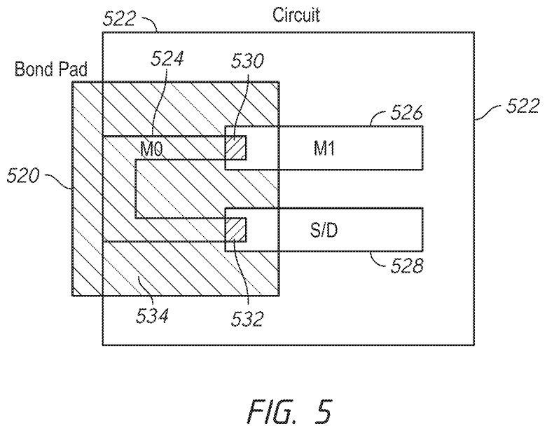

FIG. 5 is a top plan view showing the arrangement of some components in a circuit 522 relative to the bond pad 520 in accordance with examples described herein. In some examples, a metal layer, e.g., M0 layer 524 is entirely overlapped with bond pad 520, whereas metal layer M1 526 and S/D layer 528 are partially overlapped with the bond pad 520. As shown, the overlapped area 534 refers to the area under the bond pad 520 and is defined by the size of the bond pad. The M0 layer 524 is entirely overlapped with the bond pad 520 because the entire M0 layer 524 is positioned inside the overlapped area 534. M1 layer 526 and S/D layer 528 are both partially overlapped with bond pad 520 because only a portion of each of M1 layer 526 and S/D layer 528 is inside the overlapped area 534 while other portions of M1 layer 526 and S/D layer 528 are outside the overlapped area 534.

In some examples, one or more components in a circuit that is coupled to a bond pad may be positioned inside an overlapped area with the bond pad and further positioned proximate to an edge of the bond pad. For example, M0 resister layer 524, metal layer M1 526 and S/D layer 528 are all disposed proximate to an edge of the bond pad 520. This may prevent the circuit that is coupled to the bond pad from being damaged from the stress and temperature associated with forming the pin at the center of the bond pad.

Additionally, and/or alternatively, a component in a circuit that is coupled to a bond pad may be overlapped with the bond pad, where the portion of the component that is in the overlapped area may take various shapes and arrangement. For example, the M0 layer 524 may be overlapped with bond pad 520. The portion of M0 layer that is inside the overlapped area 534 may be in a U-shape. This may accommodate a length that may be required of the M0 layer. For example, M0 layer may include a resistor that has certain resistance. By forming M0 layer in a U-shape under the bond pad, the M0 layer can be entirely overlapped with the bond pad 520 and meet the length requirement. This also makes room for arranging other components in the circuit to be positioned relative to the bond pad so that those components may be overlapped to the bond pad. For example, as shown in FIG. 5, making the M0 layer 524 overlap with bond pad 520 in a U-shape may allow metal layer M1 (526) and S/D layer (528) to be overlapped or partially overlapped with the bond pad 520, resulting in a reduced pin capacitance.

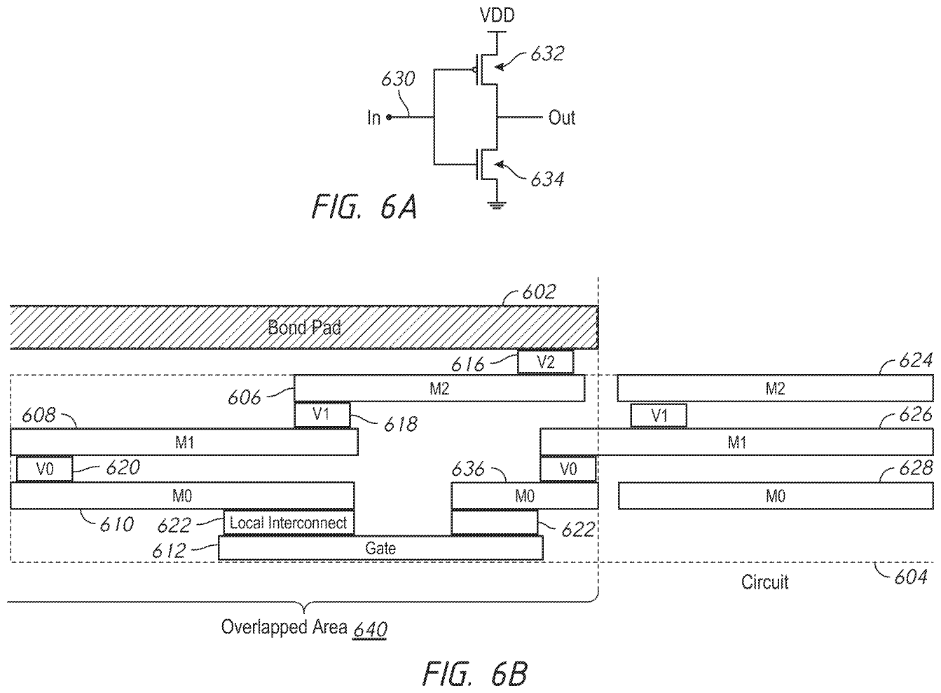

In some scenarios, other circuits coupled to the bond pads may be positioned to be overlapped with the bond pads in a similar manner. For example, the source/drain 412 of a transistor (shown in FIG. 4) may be part of an output driver of the memory device, an input driver or an ESD protection circuit. In other words, the output driver and/or the ESD protection circuit may be overlapped with the bond pad. An input driver may also be overlapped with the bond pad. This is further described with reference to FIGS. 6A-6B.

In FIG. 6A, in some scenarios, an input driver may include a pair of MOS devices 632, 634 having a common gate 630 as the input. FIG. 6B shows that a component of an input circuit, such as the example shown in FIG. 6A, may be coupled to a bond pad 602. Circuit 604 may include several components. For example, circuit 604 may include an input driver, which has a pole gate 612. Circuit 604 may include a M0 layer (610) disposed on the gate layer 612. Circuit 604 may also include one or more additional metal layers, e.g., M1 (608), M2 (606), similar to the embodiments in FIG. 4.

In some scenarios, a first layer, such as metal layer M2 (606) may be coupled to a metal layer (now shown) in the bond pad so that the circuit 604 is coupled to the bond pad 602. The first layer may be overlapped with the bond pad. For example, metal layer M2 (606) may be coupled to bond pad 602 by a conductive via 616, and may also be overlapped with bond pad 602. An additional layer, e.g., a second layer in the circuit 604 may also be overlapped with the bond pad 602. For example, portion 608 of metal M1 layer and/or portion 610 of M0 layer may be overlapped with bond pad 602, in which case, both portions 608 and 610 are entirely overlapped with the bond pad 602. Metal M1 (608) and/or M0 resistor layer (610) may also be coupled to the metal layer M2 606. Similar to FIG. 4, multiple layers of the circuit 604 may be connected via conductive vias, e.g., 620, 616, or via local interconnects (contacts), e.g., 622.

In some scenarios, other additional layers, e.g., a third layer in the circuit 604 may also be overlapped with the bond pad, where the second layer in the overlapped area 640 is disposed between the bond pad and the third layer. For example, gate layer 612 of the input driver may be overlapped with the bond pad 602 such that at least a portion of M0 layer 610 and/or a portion of M1 layer 608 is disposed between the gate layer 612 and the bond pad 602. Additionally, the third layer may be coupled to the second layer. For example, the gate layer 612 may be coupled to the M0 and/or M1 layers via local interconnect 422 or via V0. The layout of the gate layer 612 and various metal layer M0, M1, M2 may be similar to those described with reference to FIG. 4.

The various layouts described herein in FIGS. 1-6 provide advantageous over existing memory devices in accommodating larger circuits, e.g., input and output drivers that are needed for new generation memories. Further, because some layers in the circuit that are overlapped with the bond pad may have the same voltage as the pins connected to the bond pads, pin capacitance and/or the capacitance among these layers may be eliminated. Even further, the capacitances among unrelated layers which are not connected (e.g., portion 606 and 624, which are both part of M2 layer but are not connected) are also reduced because the areas of unrelated layers are reduced.

From the foregoing it will be appreciated that, although specific embodiments of the disclosure have been described herein for purposes of illustration, various modifications or combinations of various features may be made without deviating from the spirit and scope of the disclosure. For example, although some examples are described in the context of I/O bond pads, the descriptions in those examples may also be applicable to other bond pads, such as power bond pads. Further, the M0 layer shown in FIG. 5 is of a U-shape, however, other shapes may also be possible. Further, the locations of the bond pads in a die are shown to be on the edge of the die in FIG. 1, but can be anywhere in the die. Even further, some examples of the bond pads and circuits that overlap with the bond pads are shown to have M0, M1, M2 and/or M3 metal layers. However, the bond pads and the circuits may each have fewer or more metal layers, or any suitable number of metal layers, e.g., 1-3, 4, 5 or even more. In some examples, any of the metal layers in the bond pads may be coupled to any metal layer in the circuits. Accordingly, the disclosure is not limited except as by the appended claims.

1. An apparatus, comprising:
a bond pad including a metal layer; and
a circuit comprising:
a first metal layer comprising a first portion overlapped with the bond pad and a second portion extending from the first portion to outside of the bond pad; and
a second metal layer different from the first metal layer, the second metal layer comprising a U-shape portion entirely overlapped with the bond pad, wherein the U-shape portion is further coupled to the first portion of the first metal layer at a first end of the U-shape portion.

2. (canceled)

3. (canceled)

4. The apparatus of claim 1 further comprising:
a third layer overlapped with the bond pad, wherein the third layer comprises a portion also overlapped with the bond pad and coupled to a second end of the U-shape portion of the second metal layer.

5. (canceled)

6. The apparatus of claim 4, wherein the third layer is at least a portion of a source/drain of a transistor or a gate of a transistor.

7. The apparatus of claim 4, wherein the third layer is at least a portion of an input driver or an output driver of a memory.

8. The apparatus of claim 4, wherein the third layer is at least a portion of an electro-static protection circuit.

9. The apparatus of claim 4 further comprising an interconnect that couples the second layer to the third layer, wherein the interconnect is overlapped with the bond pad and is positioned at an edge of the bond pad.

10. An apparatus, comprising:
a bond pad including a metal layer; and
a circuit comprising:
a first layer comprising a first portion overlapped with the bond pad and a second portion extending from the first portion to outside the bond pad;
a metal layer comprising a U-shape portion overlapped with the bond pad; and
a transistor layer comprising a first portion overlapped with the bond pad and a second portion extending from the first portion to outside the bond pad;
wherein the first portion of the first layer is overlapped with a first end of the U-shape portion of the metal layer and the first portion of the transistor layer is overlapped with a second end of the U-shape portion of the metal layer, and wherein the first end and the second end of the U-shape portion of the metal layer are overlapped with the bond pad.

11. The apparatus of claim 10, wherein each of the first portion of the first layer or the first portion of the transistor layer is positioned at an edge of the bond pad.

12. (canceled)

13. The apparatus of claim 10 further comprising a second metal layer comprising a first portion overlapped with the bond pad and coupled to the first layer and the metal layer of the bond pad.

14. The apparatus of claim 10, wherein the transistor layer is partially overlapped with the bond pad.

15. The apparatus of claim 10, wherein the transistor layer includes a gate or a source/drain.

16. The apparatus of claim 10, wherein the transistor layer is a part of a protection circuit.

17. The apparatus of claim 10, wherein the transistor layer is a part of an input driver or a part of an output driver of a memory.

18. An apparatus, comprising:
a bond pad including a metal layer; and
a circuit comprising:
a first component that is entirely overlapped with the bond pad, wherein the first component is of a U-shape;
a second component overlapped with a first end of the U-shape of the first component; and
a third component overlapped with a second end of the U-shape of the first component.

19. The apparatus of claim 18, wherein the first component is a resistor.

20. The apparatus of claim 18, wherein:
the first component is coupled to the second component and the third component via a conductive via or a interconnect; and
one or both of the second component and the third component is partially overlapped with the bond pad.

21. The apparatus of claim 20, wherein the conductive via or the interconnect is inside an overlapped area of the bond pad, and wherein the conductive via or the local interconnect is positioned at an edge of the bond pad.

22. The apparatus of claim 18 further comprising a metal layer coupled to the first component and the bond pad, wherein the metal layer is overlapped with the bond pad.
